(19) United States
(12) Patent Application Publication
(10) Pub. No.: US 2015/0263001 A1
(43) Pub. Date: Sep. 17, 2015

(54) SEMICONDUCTOR DEVICE

(71) Applicant: KABUSHIKI KAISHA TOSHIBA, Tokyo (JP)

(72) Inventors: Yasunobu SAITO, Nomi Ishikawa (JP); Hidetoshi FUJIMOTO, Kawasaki Kanagawa (JP); Akira YOSHIOKA, Nomi Ishikawa (JP); Takeshi UCHIHARA, Kawaguchi Saitama (JP); Toshiyuki NAKA, Nonoichi Ishikawa (JP); Tasuku ONO, Nonoichi Ishikawa (JP)

(21) Appl. No.: 14/474,011

(22) Filed: Aug. 29, 2014

(30) Foreign Application Priority Data
Mar. 12, 2014 (JP) 2014-049398

(51) Int. Cl. H01L 27/07; H01L 29/20; H01L 29/205; H01L 29/778; H01L 23/528

(52) U.S. Cl. CPC H01L 27/0733; H01L 29/7787; H01L 23/528; H01L 29/205; H01L 29/2003

(57) ABSTRACT

A semiconductor device includes a first semiconductor layer and a second semiconductor layer formed on the first semiconductor layer. A first control electrode is on the first semiconductor layer with a first insulating layer between the first control electrode and the first semiconductor layer. A second control electrode is on the first semiconductor layer with a second insulating layer between the second control electrode and the first semiconductor layer, a distance between the first control electrode and the first semiconductor layer is less than a distance between the second control electrode. A wiring electrically connects the first control electrode and the second control electrode.

### CROSS-REFERENCE TO RELATED APPLICATION

This application is based upon and claims the benefit of priority from Japanese Patent Application No. 2014-049398, filed Mar. 12, 2014, the entire contents of which are incorporated herein by reference.

### FIELD

Embodiments described herein relate generally to semiconductor devices.

### BACKGROUND

Nitride semiconductor material has good material properties for some applications, such those requiring low electrical resistance or mechanical strength. A field-effect transistor having a heterojunction interface between a gallium nitride (GaN) layer and an aluminum gallium nitride (AlGaN) layer has been studied. However, since such a transistor has small gate capacitance, the transistor is vulnerable to static electricity although the small gate capacitance also allows the transistor to be fast switching.

### DESCRIPTION OF THE DRAWINGS

FIG. 1 is a cross-sectional view depicting a structure of a semiconductor device according to a first embodiment;

FIG. 2 is a graph for describing the operation a semiconductor device according to the first embodiment;

FIG. 3 is a cross-sectional view depicting a structure of a semiconductor device according to a modified example of the first embodiment;

FIG. 4 is a cross-sectional view depicting a structure of a semiconductor device according to a second embodiment;

FIG. 5 is a graph for describing the operation of a semiconductor device according to the second embodiment; and

FIG. 6 is a plan view depicting a structure of a semiconductor device according to a third embodiment.

### DETAILED DESCRIPTION

An embodiment provides a semiconductor device having improved electrostatic breakdown resistance.

In general, according to one embodiment, a semiconductor device includes a first semiconductor layer and a second semiconductor layer on a first portion of the first semiconductor layer. A first control electrode is on a second portion of the first semiconductor layer with a first insulating layer being between the first control electrode and second portion of the first semiconductor layer in a first direction. A second control electrode is on the second portion of the first semiconductor layer and spaced from the first control electrode in a second direction perpendicular to the first direction. A second insulating layer is between the second control electrode and the second portion of the first semiconductor layer. A wiring that electrically connects the first control electrode and the second control electrode is included. The device a distance in the first direction between the second control electrode and the first semiconductor layer is greater than a distance in the first direction between the first control electrode and the first semiconductor layer.

Hereinafter, embodiments will be described with reference to the drawings.

### First Embodiment

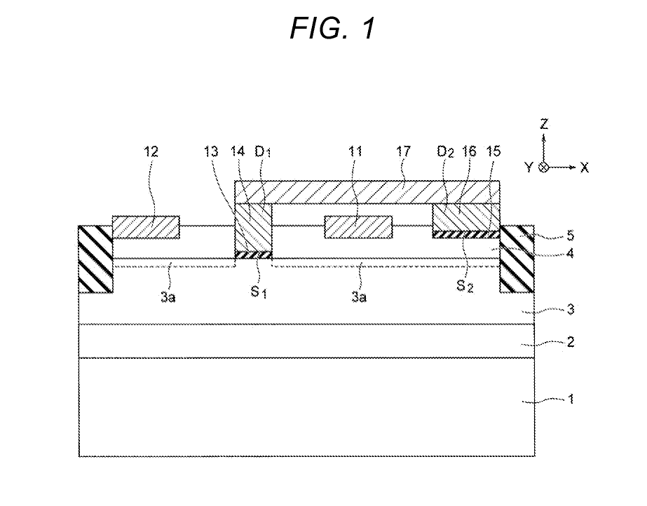

FIG. 1 is a cross-sectional view depicting the structure of a semiconductor device according to a first embodiment. The semiconductor device in FIG. 1 is a nitride semiconductor device.

The semiconductor device of FIG. 1 includes a substrate 1, a buffer layer 2, an electron travelling layer 3 (which is an example of a first semiconductor layer), an electron supply layer 4 (which is an example of a second semiconductor layer), and an element isolation area 5. The semiconductor device of FIG. 1 further includes a source electrode 11, a drain electrode 12, a first gate insulating layer 13 (which is an example of a first insulating layer), a first gate electrode 14 (which is an example of a first control electrode), a second gate insulating layer 15 (which is an example of a second insulating layer), a second gate electrode 16 (which is an example of a second control electrode), and a wiring electrode 17 (which is an example of a wiring).

The substrate 1 is, for example, a semiconductor substrate such as a silicon substrate. FIG. 1 depicts an X direction and a Y direction which are parallel to the plane of substrate 1 and are perpendicular to each other and a Z direction which is perpendicular to the plane of substrate 1. Incidentally, in this specification, a +Z direction is treated as an upward direction, and a −Z direction is treated as a downward direction. Thus, for example, the positional relation between the substrate 1 and the buffer layer 2 depicted in FIG. 1 may be expressed as follows: the substrate 1 is located below the buffer layer 2. Similarly, buffer layer 2 is located above the substrate 1.

The buffer layer 2 is formed on the substrate 1. The buffer layer 2 is, for example, a stacked film layer including an aluminum nitride (AlN) layer, an AlGaN layer, a GaN layer, and so forth. The buffer layer 2 may be doped with carbon atoms.

The electron travelling layer 3 is formed on the buffer layer 2. The electron travelling layer 3 may be referred to as a carrier layer or a channel layer. The electron travelling layer 3 is, for example, an n-type, a p-type, or an i-type (intrinsic) GaN layer. The electron travelling layer 3 may be a nitride semiconductor layer having a composition expressed as AlₓGa₁₋ₓN (0≦X≦1). A reference symbol 3a indicates a two-dimensional electron gas (2DEG) layer that is generated in the electron travelling layer 3 proximate to the interface between the electron travelling layer 3 and the electron supply layer 4.

The electron supply layer 4 is formed on the electron travelling layer 3. The electron supply layer 4 is, for example, an n-type, a p-type, or an i-type AlGaN layer. The electron supply layer 4 may be a nitride semiconductor layer having a composition expressed as Al_{y}Ga_{1-y}N (0≦Y≦1, X<Y). The electron supply layer 4 according to this embodiment has a band gap that is wider than that of the electron travelling layer 3.

The element isolation area 5 is formed on the electron travelling layer 3. The lower end of the element isolation area 5 according to this embodiment is set at a lower level than the upper end of the electron travelling layer 3. The upper end of the element isolation area 5 according to this embodiment is set at the same level as the upper end of the electron supply layer 4. When the element isolation area 5 is viewed from above, the element isolation area 5 has a shape surrounding the source electrode 11, the drain electrode 12, the first gate electrode 14, and the second gate electrode 16.

The source electrode 11 and the drain electrode 12 are formed on the electron supply layer 4 and form Ohmic contact with the electron supply layer 4. The source electrode 11 and the drain electrode 12 are formed in such a way as to place the first gate electrode 14 between the source electrode 11 and the drain electrode 12. Moreover, the source electrode 11 is formed between the first gate electrode 14 and the second gate electrode 16. Although the lower ends of the source electrode 11 and the drain electrode 12 according to this embodiment are set at a lower level than the upper end of the electron supply layer 4, the lower ends of the source electrode 11 and the drain electrode 12 may instead be set at the same level as the upper end of the electron supply layer 4.

The first gate electrode 14 is formed on the electron travelling layer 3 with the first gate insulating layer 13 interposed between the first gate electrode 14 and the electron travelling layer 3. Moreover, the first gate insulating layer 13 is in contact with the electron travelling layer 3. A lower end S₁ of the first gate electrode 14, according to this embodiment, is set at a lower level than the lower ends of the source electrode 11 and the drain electrode 12. The lower end S₁ of the first gate electrode 14 is an example of one end of the first control electrode on the side where the first insulating layer is located.

The second gate electrode 16 is formed on the electron travelling layer 3 with the second gate insulating layer 15 interposed between the second gate electrode 16 and the electron travelling layer 3. Moreover, the second gate insulating layer 15 is formed on the electron travelling layer 3 with the electron supply layer 4 interposed between the second gate insulating layer 15 and the electron travelling layer 3. The thickness of the second gate insulating layer 15, according to this embodiment, is set at the same thickness as the thickness of the first gate insulating layer 13. Furthermore, a lower end S₂ of the second gate electrode 16, according to this embodiment, is set at a higher level than the lower end S₁ of the first gate electrode 14. As a result, the distance between the lower end S₂ of the second gate electrode 16, according to this embodiment, and the electron travelling layer 3 is set so as to be greater than the distance between the lower end S₁ of the first gate electrode 14 and the electron travelling layer 3. The lower end S₂ of the second gate electrode 16 is an example of one end of the second control electrode on the side where the second insulating layer is located.

The wiring electrode 17 is formed on the first and second gate electrodes 14 and 16. Since the first gate electrode 14 and the second gate electrode 16 are electrically connected to each other by the wiring electrode 17, the same gate voltage is applied to the first and second gate electrodes 14 and 16.

The first gate electrode 14 forms a first element D₁. The first element D₁ functions as a field-effect transistor. Since the first gate electrode 14 is formed on the electron travelling layer 3 without the electron supply layer 4 interposed between the first gate electrode 14 and the electron travelling layer 3, the first element D₁ functions as a normally-off type transistor having nearly zero threshold voltage. Note that, since the first element D₁ is a normally-off type transistor, the 2DEG layer 3a does not exist in a region immediately below the first gate electrode 14.

The second gate electrode 16 forms a second element D₂. The second element D₂ functions as a field-effect transistor. Since the second gate electrode 16 is formed on the electron travelling layer 3 with the electron supply layer 4 interposed between the second gate electrode 16 and the electron travelling layer 3, the second element D₂ functions as a normally-on type transistor. Therefore, a threshold voltage of the second element D₂ has a negative value.

In this first embodiment, the distance between the lower end S₂ of the second gate electrode 16 and the electron travelling layer 3 is set so as to be greater than the distance between the lower end S₁ of the first gate electrode 14 and the electron travelling layer 3. The reason is as follows. The thicker the electron supply layer 4 between the lower ends S₁ and S₂ and the electron travelling layer 3 becomes, the lower the threshold voltages of the first and second elements D₁ and D₂ become. Therefore, the threshold voltage of the second element D₂ is set so as to be lower than the threshold voltage of the first element D₁.

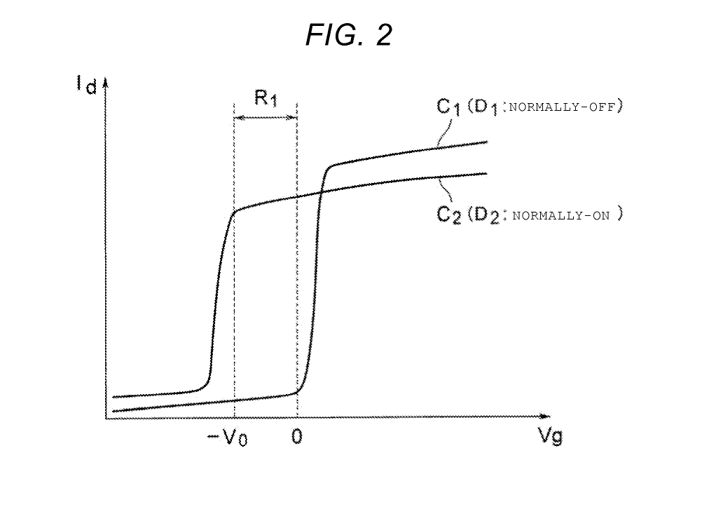

FIG. 2 is a graph for describing the operation of the first and second elements D₁ and D₂ according to the first embodiment.

The horizontal axis of FIG. 2 represents a gate voltage of the first and second elements D₁ and D₂. The vertical axis of FIG. 2 represents a drain current of the first and second elements D₁ and D₂. A curve C₁ represents an example of operating characteristics of the first element D₁. A curve C₂ represents an example of operating characteristics of the second element D₂.

The first element D₁ is a normally-off type transistor, and the threshold voltage of the first element D₁ is nearly 0. Therefore, the value of a drain current I_{d} in the curve C₁ is nearly 0 when a gate voltage V_{g} is 0.

The second element D₂ is a normally-on type transistor, and the threshold voltage of the second element D₂ is less than 0. Therefore, the value of the drain current I_{d} in the curve C₂ is positive when the gate voltage V_{g} is 0. In the curve C₂, the threshold voltage of the second element D₂ is −V₀.

A reference symbol R₁ indicates a region in which the value of the gate voltage V_{g} is from −V₀ to 0. The semiconductor device according to this embodiment may turn on the second element D₂ even when the first element D₁ is off by setting the gate voltage V_{g} of the first and second gate electrodes 14 and 16 at a value in the region R₁.

(1) Details of the Semiconductor Device According to the First Embodiment

Next, with reference to FIG. 1 again, the details of the semiconductor device according to the first embodiment will be described.

When the gate voltage V_{g} is set so as to be positive, the first element D₁ is turned on. Moreover, when the gate voltage V_{g} is set so as to be negative, the first element D₁ is turned off. In these cases, by setting the value of the gate voltage V_{g} at a value higher than −V₀, it is possible to turn on the second element D_{z} at all times irrespective of whether the first element D₁ is on or off.

When the second element D₂ is on at all times, the 2DEG layer 3a always exists in the electron travelling layer 3. The 2DEG layer 3a spreads from a region under the source electrode 11 to a region under the second gate electrode 16. Therefore, the region under the second gate electrode 16 is in a state in which the region is electrically connected to the source electrode 11.

Therefore, the second gate electrode 16, the second gate insulating layer 15, the electron travelling layer 3, and the electron supply layer 4 form an MIS (metal-oxide-semiconductor) capacitor formed of a metal layer, an insulating layer, and a semiconductor layer. The second gate electrode 16 functions as an upper electrode of the MIS capacitor, and the electron travelling layer 3 and the electron supply layer 4 function as a lower electrode of the MIS capacitor. Moreover, an electron in the 2DEG layer 3a may function as a free electron of the lower electrode.

The second gate electrode 16 is electrically connected to the first gate electrode 14 by the wiring electrode 17. Therefore, according to this embodiment, since the first gate electrode 14 is connected to an MIS capacitor, it is effectively possible to increase the gate capacitance of the first element D₁. Furthermore, by setting the value of the gate voltage V_{g} at a value higher than −V₀, the first element D₁ may always have an MIS capacitor irrespective of whether the first element D₁ is on or off.

Since the threshold voltage of the second element D₂, according to this embodiment, is lower than the threshold voltage of the first element D₁, the gate voltage V_{g} becomes lower than the threshold voltage of the first element D₁, which makes it possible to maintain an on state of the second element D₂ even after the first element D₁ is turned off. When the second element D₂ is turned off, the capacitance of the MIS capacitor fluctuates by the gate voltage V_{g}. Fluctuations in the capacitance of the MIS capacitor of the first element D₁ are undesirable from the viewpoint of the operation of the semiconductor device. However, according to this embodiment, it is possible to prevent the second element D_{z} from being turned off and therefore maintain the capacitance of the MIS capacitor at an almost constant level.

In this embodiment, the first element D₁ is used as a transistor and the second element D₂ is used as an MIS capacitor. According to this embodiment, by providing the MIS capacitor (the second element D₂) in the transistor (the first element D₁), it is possible to improve the electrostatic breakdown resistance of the transistor by the MIS capacitor.

Moreover, the MIS capacitor according to this embodiment has an MIS structure formed of a metal layer, an insulating layer, and a semiconductor layer. On the other hand, a common capacitor type has an MIM (metal-isolator-metal) structure formed of a metal layer, an insulating layer, and a metal layer. The MIS capacitor according to this embodiment has an advantage that it is possible to simplify the production process of a capacitor provided in a transistor. For example, since the semiconductor layers of the MIS capacitor according to this embodiment are the electron travelling layer 3 and the electron supply layer 4, there is no need for an extra process to form a semiconductor layer for the MIS capacitor. Furthermore, it is possible to form the second gate insulating layer 15 and the second gate electrode 16 of the MIS capacitor according to this embodiment by using the same material as the material of the first gate insulating layer 13 and the first gate electrode 14 in the same process as the first gate insulating layer 13 and the first gate electrode 14. As described above, it is possible to produce the MIS capacitor according to this embodiment by using the same materials and production processes of the transistor.

(2) Modified Example of the Semiconductor Device According to the First Embodiment

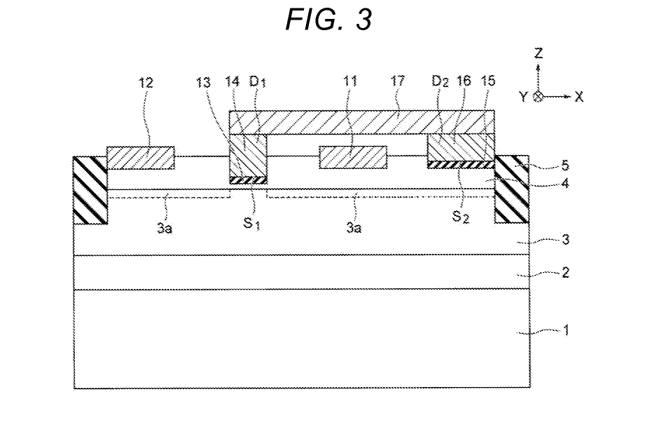

FIG. 3 is a cross-sectional view depicting the structure of a semiconductor device according to a modified example of the first embodiment.

The first gate insulating layer 13 of FIG. 1 is in contact with the electron travelling layer 3. That is, the first gate insulating layer 13 of FIG. 1 is formed on the electron travelling layer 3 without the electron supply layer 4 interposed between the first gate insulating layer 13 and the electron travelling layer 3.

On the other hand, the first gate insulating layer 13 of FIG. 3 is formed on the electron travelling layer 3 with the electron supply layer 4 interposed between the first gate insulating layer 13 and the electron travelling layer 3. However, the thickness of the electron supply layer 4 interposed between the first gate insulating layer 13 and the electron travelling layer 3 is set at a thickness that still allows the first element D₁ to function as a normally-off type transistor. This thickness is, for example, 5 nm or less.

The semiconductor device according to this embodiment may have a structure depicted in FIG. 3 in place of the structure depicted in FIG. 1.

As described above, the semiconductor device according to this modified first embodiment includes the first and second gate electrodes 14 and 16 and the wiring electrode 17 that electrically connects the first and second gate electrodes 14 and 16, and the distance between the lower end S₂ of the second gate electrode 16 and the electron travelling layer 3 is set so as to be greater than the distance between the lower end S₁ of the first gate electrode 14 and the electron travelling layer 3.

Therefore, it is possible to improve the electrostatic breakdown resistance of the transistor (the first element D₁) by the MIS capacitor (the second element D₂). It is also possible to suppress a gate-leakage current of the transistor formed by the second element D_{z} while implementing a transistor that suffers less fluctuation in threshold voltage.

### Second Embodiment

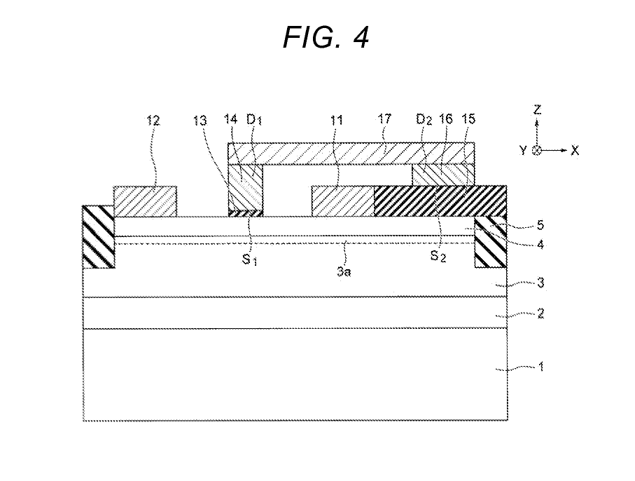

FIG. 4 is a cross-sectional view depicting the structure of a semiconductor device according to a second embodiment.

The first and second gate insulating layers 13 and 15 according to this embodiment are formed on the electron travelling layer 3 with the electron supply layer 4 interposed between the first and second gate insulating layers 13 and 15 and the electron travelling layer 3. Moreover, the thickness of the electron supply layer 4 between the first and second gate insulating layers 13 and 15 and the electron travelling layer 3 is set at a thickness that allows the first and second elements D₁ and D₂ to function as a normally-on type transistor. As a result, each of the first and second elements D₁ and D₂ functions as a normally-on type transistor. Therefore, the threshold voltages of the first and second elements D₁ and D₂ have a negative value.

The second gate insulating layer 15 is formed on the electron travelling layer 3 with the electron supply layer 4 and the element isolation area 5 interposed between the second gate insulating layer 15 and the electron travelling layer 3. Moreover, the thickness of the second gate insulating layer 15 is set so that the second gate insulating layer 15 becomes thicker than the first gate insulating layer 13. Furthermore, the distance between the lower end S₂ of the second gate electrode 16 and the electron travelling layer 3 (the 2DEG layer 3a) is set so as to be greater than the distance between the lower end S₁ of the first gate electrode 14 and the electron travelling layer 3 (the 2DEG layer 3a). The threshold voltage of the second element D₂ is thus set so as to be lower than the threshold voltage of the first element D₁.

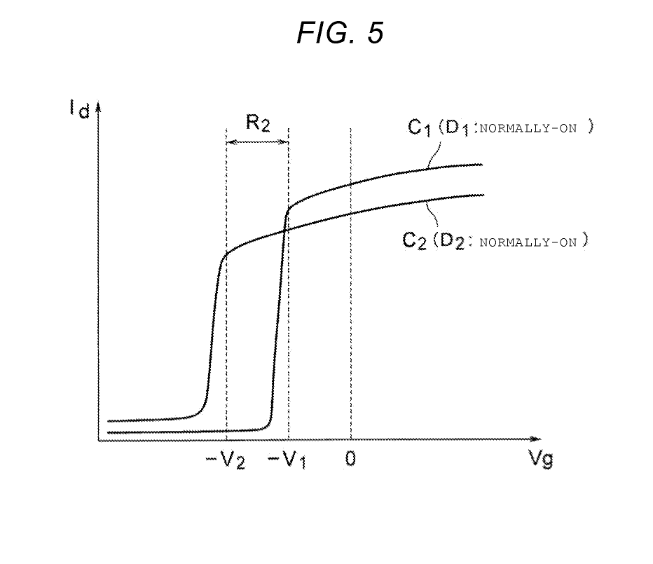

FIG. 5 is a graph for describing the operation of the first and second elements D₁ and D₂ according to the second embodiment.

The first element D₁ is a normally-on type transistor, and the threshold voltage of the first element D₁ is less than 0. Therefore, the value of the drain current I_{d} in the curve C₁ is positive when the gate voltage V_{g} is 0. In the curve C₁, the threshold voltage of the first element D₁ is −V₁.

The second element D₂ is also a normally-on type transistor, and the threshold voltage of the second element D₂ is less than 0. Therefore, the value of the drain current I_{d} in the curve C₂ is positive when the gate voltage V_{g} is 0. In the curve C₂, the threshold voltage of the second element D₂ is −V₂. The threshold voltage −V₂ of the second element D₂ is set so as to be lower than the threshold voltage −V₁ of the first element D₁.

A reference symbol R₂ indicates a region in which the value of the gate voltage V_{g} is from −V₂ to −V₁. The semiconductor device according to this embodiment may turn on the second element D₂ even when the first element D₁ is off by setting the gate voltage V_{g} of the first and second gate electrodes 14 and 16 at a value in the region R₂.

(1) Details of the Semiconductor Device According to the Second Embodiment

When the gate voltage V_{g} is set so as to be higher than −V₁, the first element D₁ is turned on. Moreover, when the gate voltage V_{g} is set so as to be lower than −V₁, the first element D₁ is turned off. In these cases, by setting the value of the gate voltage V_{g} at a value higher than −V₂, it is possible to turn on the second element D₂ at all times irrespective of whether the first element D₁ is on or off.

When the second element D₂ according to this embodiment is on at all times, the 2DEG layer 3a always exists in the electron travelling layer 3. The 2DEG layer 3a spreads from the region under the source electrode 11 to the region under the second gate electrode 16. Therefore, the region under the second gate electrode 16 is in a state in which the region is electrically connected to the source electrode 11.

Therefore, as in the first embodiment, the second gate electrode 16, the second gate insulating layer 15, the electron travelling layer 3, and the electron supply layer 4 according to this embodiment form an MIS capacitor formed of a metal layer, an insulating layer, and a semiconductor layer. The second gate electrode 16 functions as an upper electrode of the MIS capacitor, and the electron travelling layer 3 and the electron supply layer 4 function as a lower electrode of the MIS capacitor. Moreover, electrons in the 2DEG layer 3a may function as a free electron of the lower electrode.

As described above, the semiconductor device according to this second embodiment includes the first and second gate electrodes 14 and 16 and the wiring electrode 17 that electrically connects the first and second gate electrodes 14 and 16, and the distance between the lower end S₂ of the second gate electrode 16 and the electron travelling layer 3 is set so as to be greater than the distance between the lower end S₁ of the first gate electrode 14 and the electron travelling layer 3.

Therefore, according to this second embodiment, as in the first embodiment, it is possible to improve the electrostatic breakdown resistance of the transistor (the first element D₁) by use of the MIS capacitor (the second element D₂).

### Third Embodiment

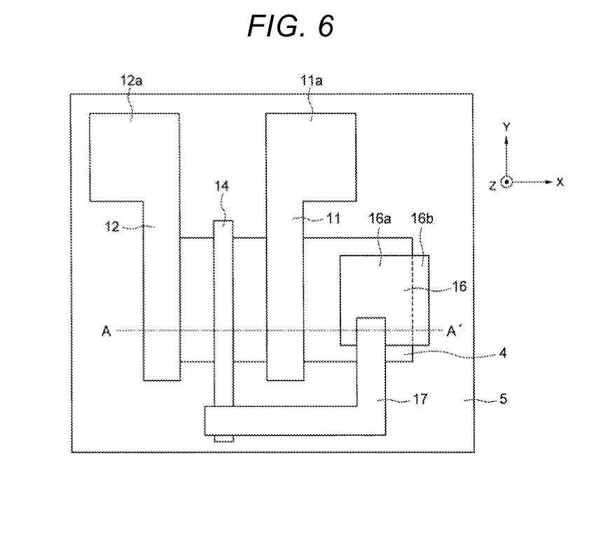

FIG. 6 is a plan view depicting the structure of a semiconductor device according to a third embodiment.

A cross section taken on the line A-A′ in the plan view of FIG. 6 corresponds to the sectional view of FIG. 4. However, the whole of the wiring electrode 17, and not just a part of the wiring electrode 17 as is depicted in FIG. 4, is depicted in FIG. 6.

The semiconductor device of FIG. 6 includes a source pad 11a forming the source electrode 11 and a drain pad 12a forming the drain electrode 12. The source pad 11a and the drain pad 12a are disposed on the element isolation area 5. In this embodiment, the source pad 11a is used as a bonding pad for the source electrode 11 and the drain pad 12a is used as a bonding pad for the drain electrode 12.

The electron supply layer 4 depicted in FIG. 6 corresponds to an element region of the semiconductor device. The element isolation area 5 according to this embodiment has a shape surrounding the element region.

The semiconductor device of FIG. 6 differs from the semiconductor device of FIG. 4 in that the second gate electrode 16 is formed on the second gate insulating layer 15 and the element isolation area 5. The second gate electrode 16 of FIG. 6 is formed to have a size and a position that make it possible to use the second gate electrode 16 as a bonding pad (a gate pad) for the first and second gate electrodes 14 and 16. The second gate electrode 16 of FIG. 6 has first and second regions 16a and 16b. The first region 16a is formed on the electron supply layer 4 with the second gate insulating layer 15 interposed between the first region 16a and the electron supply layer 4. The second region 16b is formed on the element isolation area 5.

When the second gate electrode 16 is added to the semiconductor device, there would typically be apprehension that the element area of the semiconductor device may have to increase due to the addition of the second gate electrode 16. However, since the second gate electrode 16 according to this embodiment is also a gate pad, it is possible to add the second gate electrode 16 to the semiconductor device without increasing the element area of the semiconductor device.

Moreover, according to this third embodiment, by adjusting the area and the area ratio of the first and second regions 16a and 16a, it is possible to adjust the capacitance of the above-described MIS capacitor.

Incidentally, the structure of the second gate electrode 16 according to this embodiment may be applied not only to the second embodiment but also to the first embodiment.

Moreover, in the first to third embodiments, any materials and structures may be adopted as the materials and structures of the substrate 1 and the buffer layer 2. Moreover, the first to third embodiments may also be applied to a semiconductor device provided with other transistors and diodes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first semiconductor layer;
a second semiconductor layer on a first portion of the first semiconductor layer;
a first control electrode on a second portion of the first semiconductor layer, a first insulating layer being between the first control electrode and second portion of the first semiconductor layer in a first direction;
a second control electrode on the second portion of the first semiconductor layer and spaced from the first control electrode in a second direction perpendicular to the first direction, a second insulating layer being between the second control electrode and the second portion of the first semiconductor layer; and
a wiring that electrically connects the first control electrode and the second control electrode, wherein
a distance in the first direction between the second control electrode and the first semiconductor layer is greater than a distance in the first direction between the first control electrode and the first semiconductor layer.

2. The semiconductor device according to claim 1, wherein the first insulating layer directly contacts the first semiconductor layer.

3. The semiconductor device according to claim 1, wherein a portion of the second semiconductor layer is between the first insulating layer and the first portion of the first semiconductor layer in the first direction.

4. The semiconductor device according to claim 1, wherein the second electrode extends in the first direction into the second semiconductor layer, and the second insulating layer is directly contacting the second semiconductor layer.

5. The semiconductor device according to claim 1, wherein the second insulating layer has a thickness in the first direction that is greater than a thickness in the first direction of the first insulating layer.

6. The semiconductor device according to claim 1, wherein
a distance in the first direction from a surface of the second insulating layer that is contacting the second semiconductor layer to a surface of the first semiconductor layer that is contacting the second semiconductor layer is the same as a distance in the first direction from a surface of the first insulating layer that is contacting the second semiconductor layer to the surface of the first semiconductor layer that is contacting the second semiconductor layer, and
the second insulating layer has a thickness in the first direction that is greater than a thickness in the first direction of the first insulating layer.

7. The semiconductor device according to claim 1, wherein a threshold voltage of a second element including the second control electrode is lower than a threshold voltage of a first element including the first control electrode.

8. The semiconductor device according to claim 7, wherein the first element is a normally-off type element, and the second element is a normally-on type element.

9. The semiconductor device according to claim 7, wherein each of the first and second elements is a normally-on type element.

10. The semiconductor device according to claim 1, further comprising:
an element isolation area on a third portion of the first semiconductor layer, the third portion surrounding the first and second portions when viewed along the first direction.

11. A semiconductor device, comprising:
a first semiconductor layer;
a second semiconductor layer on a first portion of the first semiconductor layer;
an element isolation area on a second portion of the first semiconductor layer;
a first control electrode on a third portion of the first semiconductor layer, a first insulating layer being between the first control electrode and the third portion of the first semiconductor layer in a first direction;
a second control electrode that is formed on the first portion of the first semiconductor layer, a second insulating layer being between the second control electrode and the first portion of the first semiconductor layer, a portion of the second control electrode being on the element isolation area; and
a wiring that electrically connects the first control electrode and the second control electrode.

12. The semiconductor device according to claim 11, a distance in the first direction between the second control electrode and the first semiconductor layer is greater than a distance in the first direction between the first control electrode and the first semiconductor layer.

13. The semiconductor device according to claim 11, wherein a thickness of the second insulating layer in the first direction is greater than a thickness of the first insulating layer in the first direction.

14. The semiconductor device according to claim 13, wherein, the second insulating layer is between the second electrode and the element isolation area in the first direction.

15. The semiconductor device according to claim 11, wherein the second electrode comprises a bonding pad.

16. The semiconductor device according to claim 11, wherein the wiring has a portion that is on the element isolation area.

17. A semiconductor device, comprising:
a first element including:
a first control electrode on a first portion of a first semiconductor layer;
a first insulating layer on the first portion on the first semiconductor layer and between the first control electrode and the first semiconductor layer;
a second semiconductor layer on a second portion of the first semiconductor layer;
a drain electrode on the second semiconductor layer and spaced from the first control electrode in a first direction that is parallel to the first semiconductor layer; and
a source electrode on the second semiconductor layer and spaced from the first control electrode in the first direction, the first control electrode being between the source and drain electrodes in the first direction;
a second element including:
a second control electrode on the second portion of the first semiconductor layer and spaced from the first control electrode in the first direction; and
a second insulating layer between the second control electrode and the second portion of the first semiconductor layer; and
a wiring electrically connecting the first and second control electrodes, wherein
a distance in a second direction between the second control electrode and the first semiconductor layer is greater than a distance in the second direction between the first control electrode and the first semiconductor layer, the second direction being orthogonal to the first semiconductor layer.

18. The semiconductor device according to claim 17, wherein the first element is a normally OFF transistor.

19. The semiconductor device according to claim 17, wherein the first element is a normally ON transistor.

20. The semiconductor device according to claim 17, wherein the second element is a capacitor.
